(19) United States
(12) Patent Application Publication
(10) Pub. No.: US 2024/0105815 A1
(43) Pub. Date: Mar. 28, 2024

(54) SEMICONDUCTOR STRUCTURE AND METHOD OF MANUFACTURE

(71) Applicant: Taiwan Semiconductor Manufacturing Company Limited, Hsin-Chu (TW)

(72) Inventors: Chin-Yi HUANG, HsinChu City (TW); Shih Chan WEI, New Taipei City (TW); Wei Kai SHIH, Nantou County (TW)

(21) Appl. No.: 18/126,690

(22) Filed: Mar. 27, 2023

Related U.S. Application Data
(60) Provisional application No. 63/409,878, filed on Sep. 26, 2022.

(51) Int. Cl. H01L 29/66; H01L 29/06; H01L 29/40; H01L 29/78

(52) U.S. Cl. CPC H01L 29/66674; H01L 29/0653; H01L 29/404; H01L 29/7801

(57) ABSTRACT

A semiconductor structure and method of manufacture is provided. In some embodiments, a semiconductor structure includes a semiconductor layer, a first isolation structure in the semiconductor layer, a first gate structure adjacent a first side of the first isolation structure, a first source/drain region adjacent a second side of the first isolation structure, a second source/drain region adjacent the first gate structure, and a first conductive field plate at least partially embedded in the first isolation structure.

### CROSS-REFERENCE TO RELATED APPLICATION

This application claims priority to U.S. Patent Application 63/409,878, titled “SEMICONDUCTOR STRUCTURE AND METHOD OF MANUFACTURE” and filed on Sep. 26, 2022, which is incorporated herein by reference.

### BACKGROUND

Semiconductor structures are used in a multitude of electronic devices, such as consumer products, industrial electronics, appliances, aerospace devices, and transportation devices. Some semiconductor structures include metal-oxide-semiconductor field-effect transistors (MOSFETs). One type of MOSFET is a double diffused MOS (DMOS). In comparison with other MOSFETs, the DMOS is capable of delivering more current per unit area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 are illustrations of a semiconductor structure at various stages of fabrication, in accordance with some embodiments.

FIG. 12 is an illustration of a semiconductor structure, in accordance with some embodiments.

### DETAILED DESCRIPTION

The following disclosure provides many different embodiments, or examples, for implementing different features of the provided subject matter. Specific examples of components and structures are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present application relates to a semiconductor structure and a method for fabricating a semiconductor structure. In accordance with some embodiments, a device, such as a DMOS device, is formed by forming an isolation structure in a semiconductor layer, forming a gate structure over the semiconductor layer adjacent a first side of the isolation structure, forming a first source/drain region in the semiconductor layer adjacent the gate structure, and forming a second source/drain region adjacent the isolation structure. Source/drain region(s) may refer to a source or a drain, individually or collectively dependent upon the context. For example, the first source/drain region is a source region, and the first source/drain region is a drain region. A trench is formed in the isolation structure and at least a portion of a field plate is formed in the trench. The field plate reduces the surface electric field of the DMOS device, thereby increasing a performance of the DMOS device by lowering the breakdown voltage.

In some embodiments, a second device may be formed by forming a second isolation structure, a third source/drain region, and a second gate structure in and over the semiconductor layer on the other side of the second source/drain region. The second source/drain region may be shared by the devices.

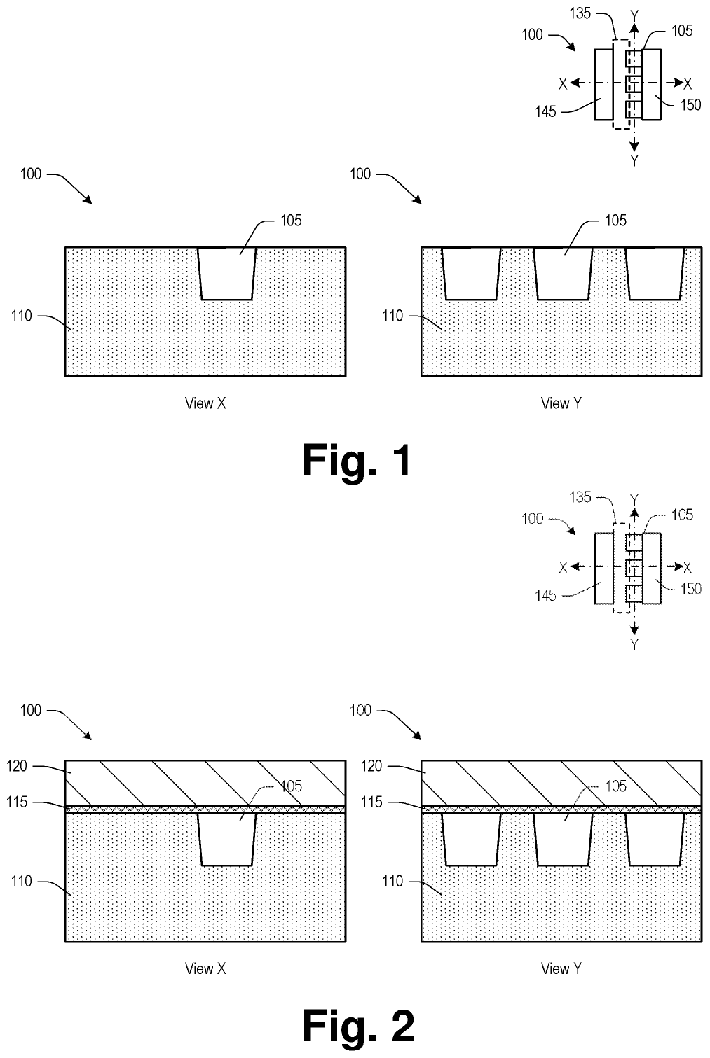

FIGS. 1-11 illustrate a semiconductor structure 100 at various stages of fabrication, in accordance with some embodiments. In FIGS. 1-11, views labeled “X” are cross-sectional views taken through the semiconductor structure 100 in a direction corresponding to a gate length direction and views labeled “Y” are cross-sectional views taken through the semiconductor structure 100 in a direction corresponding to a gate width direction. FIGS. 1-11 include a simplistic plan view showing where various cross-sectional views are taken. Not all aspects of the processing shown in the cross-sectional views will be depicted in the plan view.

Referring to FIG. 1, a shallow trench isolation (STI) structure 105 is formed in a semiconductor layer 110, in accordance with some embodiments. In some embodiments, the semiconductor layer 110 is part of a substrate comprising at least one of an epitaxial layer, a single crystalline semiconductor material such as, but not limited to, at least one of Si, Ge, SiGe, InGaAs, GaAs, InSb, GaP, GaSb, InAlAs, GaSbP, GaAsSb, or InP, a silicon-on-insulator (SOI) structure, a wafer, or a die formed from a wafer. In some embodiments, the semiconductor layer 110 comprises at least one of crystalline silicon or other suitable materials. Other structures and/or configurations of the semiconductor layer 110 are within the scope of the present disclosure.

In some embodiments, the STI structure 105 is formed by forming at least one mask layer over the semiconductor layer 110. In some embodiments, the at least one mask layer comprises a layer of oxide material over the semiconductor layer 110 and a layer of nitride material over the layer of oxide material, and/or one or more other suitable layers. At least one of the at least one mask layer is removed to form an etch mask for use as a template to etch the semiconductor layer 110 to form a trench. A dielectric material is formed in the trench to form the STI structure 105. In some embodiments, the STI structure 105 includes multiple layers, such as an oxide liner, a nitride liner formed over the oxide liner, an oxide fill material formed over the nitride liner, and/or other suitable materials. In some embodiments, the STI structure 105 comprises multiple portions, such as the three portions. The number of portions may vary. In some embodiments, the STI structure 105 comprises a single portion creating a contiguous structure in the Y-direction.

In some embodiments, a fill material of the STI structure 105 is formed using a high density (HDP) plasma process. The HDP process uses precursor gases comprising at least one of silane (SiH₄), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition. In accordance with some embodiments, argon and oxygen act as sputtering sources, and the particular values of the gas ratios are determined based on an aspect ratio of the trench. After forming the fill material, an anneal process is performed to densify the fill material. In some embodiments, the STI structure 105 generates compressive stress that serves to compress a portion of the semiconductor layer 110. Other structures and/or configurations of the STI structure 105 are within the scope of the present disclosure.

Although the semiconductor layer 110 and the STI structure 105 are illustrated as having coplanar upper surfaces at an interface where the semiconductor layer 110 abuts the STI structure 105, the relative heights can vary. For example, the STI structure 105 can be recessed relative to the semiconductor layer 110, or the semiconductor layer 110 can be recessed relative to the STI structure 105. The relative heights at the interface depend on the processes performed for forming the STI structure 105, such as at least one of deposition, planarization, mask removal, surface treatment, or other suitable techniques.

Referring to FIG. 2, a gate dielectric layer 115 and a gate electrode layer 120 are formed over the semiconductor layer 110 and the STI structure 105, in accordance with some embodiments. In some embodiments, the gate dielectric layer 115 comprises silicon dioxide, a high-k dielectric, or some other suitable gate dielectric layer material. As used herein, the term “high-k dielectric” refers to the material having a dielectric constant, k, greater than or equal to about 3.9, which is the k value of SiO₂. The high-k dielectric material may comprise any suitable materials. Examples of the high-k dielectric material include, but are not limited to, Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, an alloy thereof, and/or other suitable materials. Each value of x is independently from 0.5 to 3, and each value of y is independently from 0 to 2. In some embodiments, the gate dielectric layer 115 comprises a native oxide layer formed by exposure of the semiconductor structure 100 to oxygen at various points in the process flow, causing the formation of silicon dioxide on exposed surfaces. In some embodiments, an additional layer of dielectric material, such as comprising silicon dioxide, a high-k dielectric material, and/or other suitable materials, is formed over the native oxide to form the gate dielectric layer 115.

In some embodiments, the gate electrode layer 120 comprises polysilicon, metal, or some other suitable gate electrode material. In some embodiments, the initial layer of gate dielectric material and the initial layer of gate electrode material are sacrificial layers, and the sacrificial gate dielectric layer is later replaced with a replacement gate dielectric layer and the sacrificial layer of gate electrode material is replaced with a replacement gate electrode. A metal gate electrode layer may comprise a barrier layer, one or more work function material layers, a seed layer, a metal fill layer, and/or other suitable layers. In some embodiments, the metal fill layer comprises tungsten, aluminum, copper, cobalt, and/or other suitable materials. In some embodiments, the gate dielectric layer 115 and/or the one or more layers that comprise the gate electrode layer 120 are formed by at least one of atomic layer deposition (ALD), physical vapor deposition (PVD), chemical vapor deposition (CVD), low pressure CVD (LPCVD), atomic layer chemical vapor deposition (ALCVD), ultrahigh vacuum CVD (UHVCVD), reduced pressure CVD (RPCVD), molecular beam epitaxy (MBE), plating, or other suitable techniques.

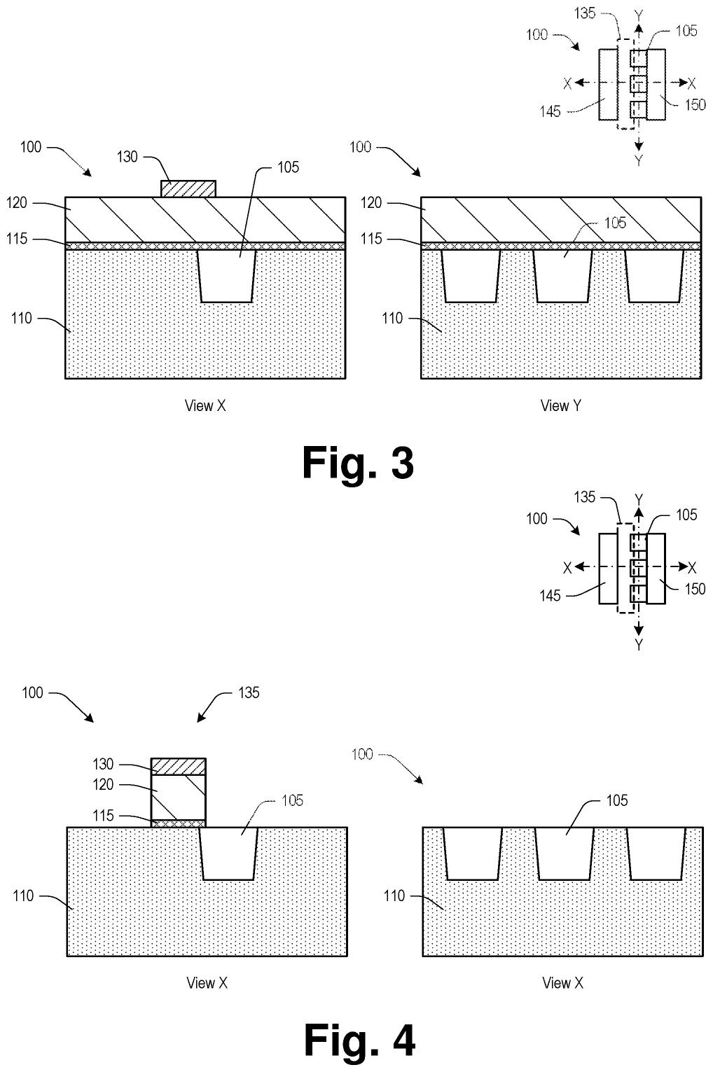

Referring to FIG. 3, a gate mask 130 is formed over the gate electrode layer 120, in accordance with some embodiments. In accordance with some embodiments, the gate mask 130 comprises a plurality of individually formed layers that together form a mask stack. In some embodiments, the gate mask 130 comprises at least one of a hard mask layer, a bottom antireflective coating (BARC) layer, an organic planarization layer (OPL), or a photoresist layer. The hard mask layer is formed by at least one of physical vapor deposition (PVD) (e.g., sputtering and/or evaporation), chemical vapor deposition (CVD) (e.g., low pressure CVD (LPCVD), ultrahigh vacuum CVD (UHVCVD), reduced pressure CVD (RPCVD), plasma-enhanced CVD (PECVD), and/or atmospheric pressure CVD (APCVD)), spin on, growth, or other suitable techniques. In some embodiments, the hard mask layer comprises at least one of silicon and oxygen, silicon and nitrogen, nitrogen, silicon (e.g., polycrystalline silicon), or other suitable materials. In some embodiments, the BARC layer is a polymer layer that is applied using a spin coating process. In some embodiments, the OPL comprises a photo-sensitive organic polymer that is applied using a spin coating process. In some embodiments, the OPL comprises a dielectric layer. In some embodiments, the photoresist layer is formed by at least one of spinning, spray coating, or other suitable techniques. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer. The layers of the mask stack are patterned to form the gate mask 130. In some embodiments, the photoresist layer is exposed using a radiation source and a reticle to define a pattern in the photoresist layer, and portions of the photoresist layer are removed to define a patterned photoresist layer. The underlying OPL, BARC layer, and hard mask layer are etched using the patterned photoresist layer as a template to form the gate mask 130 and expose portions of the gate electrode layer 120 under the gate mask 130. Other structures and configurations of the gate mask 130 within the scope of the present disclosure.

Referring to FIG. 4, a patterning process is performed to form a gate structure 135 including the gate dielectric layer 115 and the gate electrode layer 120, in accordance with some embodiments. An etching processes is performed using the gate mask 130 as an etch template to pattern the gate electrode layer 120 and gate dielectric layer 115 to form the gate structures 135. In some embodiments, the etching process is at least one of a plasma etching process, a reactive ion etching (RIE) process, or other suitable techniques. In some embodiments, the gate mask 130 remains over the gate electrode layer 120 and functions as a cap layer. The gate structure 135 may overlap a portion of the STI structure 105. Other configurations of the gate structure 135 are within the scope of the present disclosure.

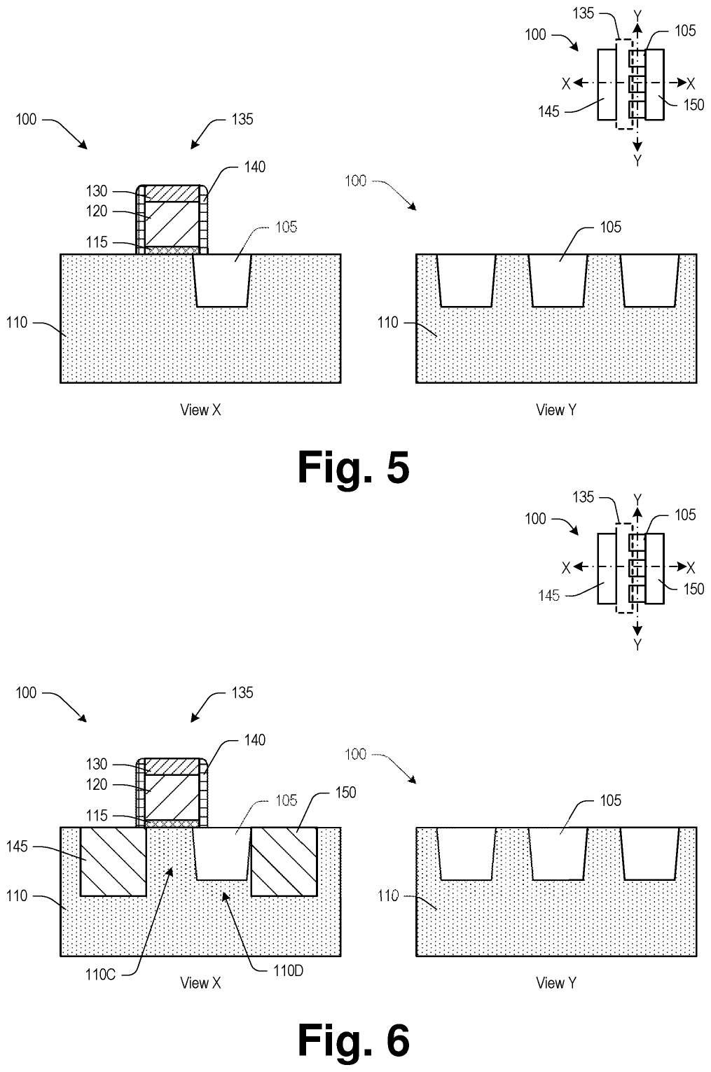

Referring to FIG. 5, a sidewall spacer 140 is formed adjacent the gate mask 130, the gate electrode layer 120, and the gate dielectric layer 115, in accordance with some embodiments. In some embodiments, the sidewall spacer 140 is formed by depositing a conformal spacer layer over the gate mask 130, gate electrode layer 120, and the gate dielectric layer 115 and performing an anisotropic etch process to remove portions of the spacer layer positioned on horizontal surfaces of the gate mask 130, the semiconductor layer 110, and the STI structure 105. In some embodiments, the sidewall spacer 140 comprises the same material composition as the gate mask 130. In some embodiments, the sidewall spacer 140 comprises nitrogen, silicon and/or other suitable materials. Other structures and/or configurations of the sidewall spacer 140 are within the scope of the present disclosure.

Referring to FIG. 6, source/drain regions 145, 150 are formed in the semiconductor layer 110, in accordance with some embodiments. In some embodiments, the source/drain region 145 is formed in the semiconductor layer 110 adjacent the sidewall spacer 140 using the gate structure 135 and sidewall spacer 140 as a self-aligned implantation mask. In some embodiments, the source/drain region 150 is formed adjacent the STI structure 105. A portion of the semiconductor layer 110 under the gate structure 135 forms a channel region 110C, and a portion of the semiconductor layer 110 under the STI structure 105 forms a drift region 110D between the channel region 110C and the source/drain region 150.

In some embodiments, the source/drain regions 145 and the source/drain region 150 are formed by implantation of dopants, also referred to as impurities, into the semiconductor layer 110. In some embodiments, such as where a resulting transistor is an n-type DMOS device, the source/drain regions 145, 150 comprise an n-type impurity, such as at least one of phosphorous, arsenic, or other suitable n-type dopants, and the semiconductor layer 110 in at least the channel region 110C, comprises a p-type dopant, such as at least one of boron, BF₂, or other suitable p-type dopants. In some embodiments, such as where a resulting transistor is a p-type DMOS device, the source/drain regions 145, 150 comprise a p-type impurity, and the semiconductor layer 110, in at least the channel region 110C, comprises an n-type dopant. In some embodiments, one or more implantation processes are performed to tailor the dopant profiles of the source/drain regions 145, 150. For example, a tilted implantation using a dopant having a conductivity type opposite the conductivity type of the dopant in the source/drain regions 145, 150 may be implanted under the sidewall spacer 140 to form halo regions, in accordance with some embodiments. In some embodiments, an implantation process is performed to form a lightly doped region under the sidewall spacers 140.

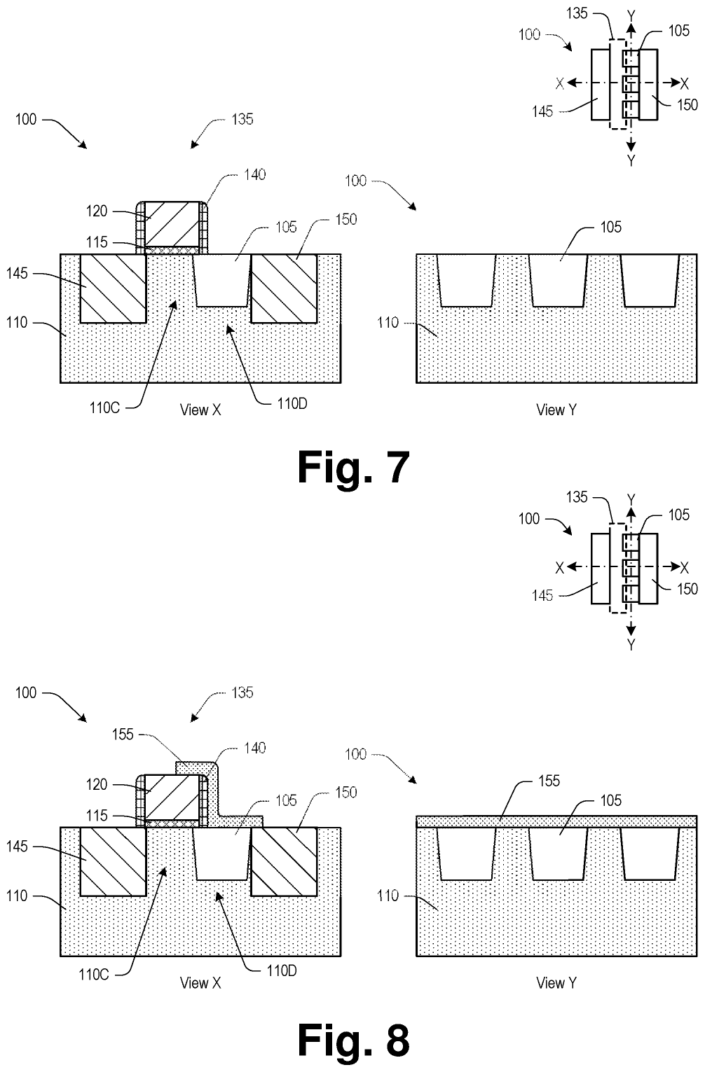

Referring to FIG. 7, the gate mask 130 is removed, in accordance with some embodiments. The gate mask 130 may be removed by forming a sacrificial layer, such as a sacrificial dielectric layer over the gate structure 135 and the gate mask 130 and performing a planarizing process to remove portions of the sacrificial layer, the gate mask 130, and the sidewall spacer 140. After the planarization process, a selective etch process may be performed to remove the sacrificial layer.

Referring to FIG. 8, a dielectric layer 155 having a first portion over a portion of the gate structure 135, a second portion over a portion of the sidewall spacer 140, a third portion over a portion of the semiconductor layer 110, and a fourth portion over the STI structure 105 is formed, in accordance with some embodiments. In some embodiments, the dielectric layer 155 is formed by forming a conformal layer over the gate structure 135 and performing a patterning process to remove a portion of dielectric layer 155 over the gate structure 135, a portion of the dielectric layer 155 over the semiconductor layer 110, and a portion of the dielectric layer 155 over the source/drain region 150. In some embodiments, the patterning process uses a mask, such as a photoresist mask or a mask stack comprising at least one of a hard mask layer, a BARC layer, an OPL, or a photoresist layer comprising materials and formed as described herein. A plasma etch process is used to remove portions of the dielectric layer 155 not covered by the photoresist mask. In some embodiments, the dielectric layer 155 comprises a resist protective oxide (RPO) layer having a higher porosity than silicon dioxide. The plasma etch process for patterning the dielectric layer 155 may use a carbon fluoride (C₄F₈) etch gas.

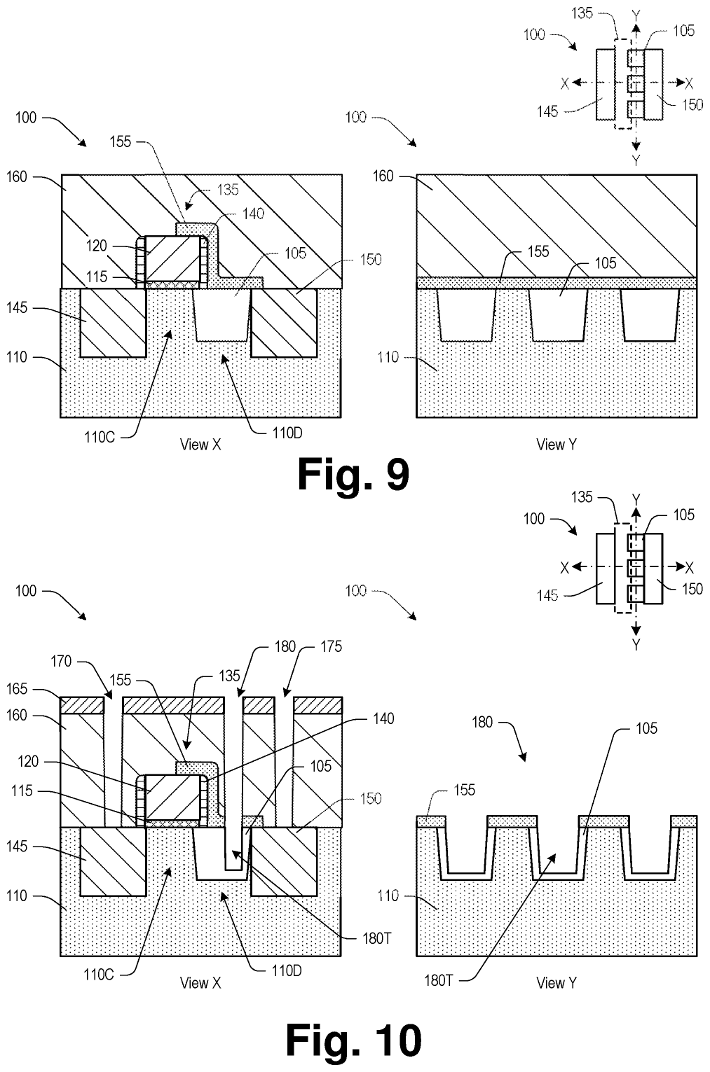

Referring to FIG. 9, a dielectric layer 160 is formed over the gate structure 135, the dielectric layer 155, and the semiconductor layer 110, in accordance with some embodiments. The dielectric layer 160 comprises silicon dioxide, a low-k dielectric material, one or more layers of low-k dielectric material, and/or other suitable materials. Low-k dielectric materials have a k value lower than about 3.9. The materials for the dielectric layer 160 comprise at least one of Si, O, C, or H, such as carbon doped oxide dielectrics, SiCOH or SiOC, or other suitable materials. Organic material such as polymers may be used for the dielectric layer 160. The dielectric layer 160 may comprise at least one of a carbon-containing material, organo-silicate glass, a porogen-containing material, nitrogen, and/or or other suitable materials. The dielectric layer 160 may be formed by at least one of ALD, CVD, LPCVD, ALCVD, UHVCVD, RPCVD, PECVD, MBE, LPE, spin coating, spin-on technology, or other suitable techniques.

Referring to FIG. 10, a contact mask 165 is formed over the dielectric layer 160 and a patterning process is performed to form contact openings 170, 175, 180 in accordance with some embodiments. In some embodiments, the contact mask 165 is formed using at least one of a hard mask layer, a BARC layer, an OPL, or a photoresist layer comprising materials and formed as described herein. An etching processes is performed using the contact mask 165 as an etch template to pattern the dielectric layer 160, the dielectric layer 155, and the STI structure 105 to form the contact openings 170, 175, 180. Although a single contact mask 165 and etching process is illustrated, the patterning process may employ multiple masks and multiple etching processes with different etch chemistries to form the contact openings 170, 175, 180. The contact opening 170 exposes the source/drain region 145, the contact opening 175 exposes the source/drain region 150, and the contact opening 180 defines a recess, such as a trench 180T, extending into the STI structure 105. In some embodiments, the etching process is at least one of a plasma etching process, a reactive ion etching (RIE) process, or other suitable techniques.

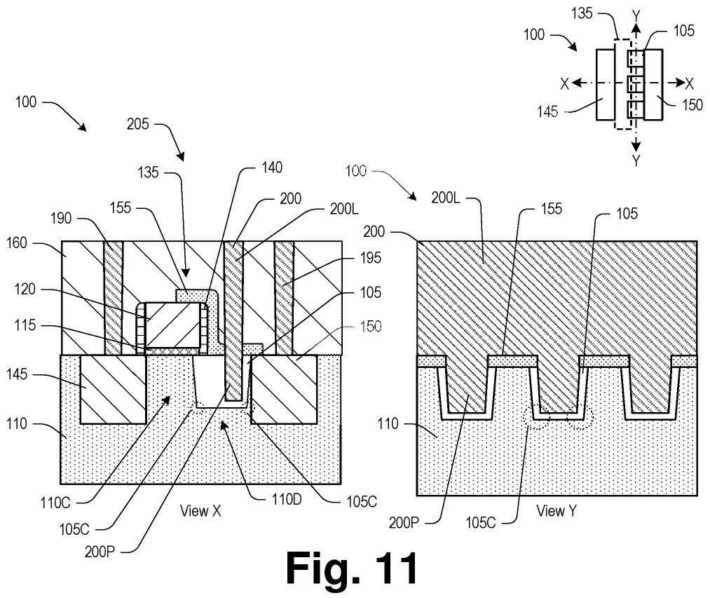

Referring to FIG. 11, contacts 185, 190 are formed in the contact openings 170, 175, and a conductive field plate 200 is formed in the contact opening 180, in accordance with some embodiments. In some embodiments, the contacts 185, 190 and the conductive field plate 200 are formed by forming a conductive layer over the dielectric layer 160 and in the contact openings 170, 175, 180. In some embodiments, the contacts 195, 190 and the conductive field plate 200 comprise a barrier layer, a seed layer, a metal fill layer, and/or other suitable layers. The metal fill layer comprises W, Al, Cu, Co, and/or other suitable materials. The contacts 195, 190 and the conductive field plate 200 may be formed by forming the layers of the contacts 195, 190 and the conductive field plate 200 in the contact openings 170, 175, 180 and over the dielectric layer 160. A planarization process is performed to remove portions of the contacts 195, 190 and the conductive field plate 200 outside the openings and over the dielectric layer 160. Other structures and/or configurations of the contacts 185, 190 and the conductive field plate 200 are within the scope of the present disclosure.

In some embodiments, one or more gate contacts (not visible in FIG. 11) may be formed to contact the gate structure 135. The gate contact may be formed in a different position along the axial length of the gate structure 135, such as into or out of the page as compared to the position of the contacts 185, 190 and the conductive field plate 200. Although the contacts 185, 190 and the conductive field plate 200 are illustrated as being in the same axial position along the length of the semiconductor structure 100, the contacts 185, 190 and the conductive field plate 200 may be formed at different axial positions into or out of the page. Multiple contacts 185, 190 conductive field plates 200 may be formed along the axial length of the gate structure 135. As shown in the plan view three conductive field plates 200 are formed over three STI structures 105 along the axial length of the drift region 110D. The number of conductive field plates 200 may vary. Multiple contacts 185, 190 may be formed along the axial lengths of the source/drain region 145 and the source/drain region 150, respectively.

The source/drain regions 145, the source/drain region 150, the gate structure 135, the dielectric layer 155, and the conductive field plate 200 form a DMOS device 205 with the drift region 110D formed between the gate structure 135 and the source/drain region 150. The conductive field plate 200 promoted a uniform electric field for the DMOS device 205 to reduce the breakdown voltage of the DMOS device 205. The conductive field plate 200 comprises a line portion 200L over the dielectric layer 155 and plug portions 200P in the STI structure 105. The plug portions 200P of the conductive field plate 200 in the STI structure 105 reduce the surface electric field in the drift region 110D. In some embodiments, the plug portions 200P of the conductive field plate 200 in the STI structure 105 reduce the surface electric field in corner interface regions 105C between the STI structure 105 and the semiconductor layer 110. In some embodiments, a voltage is applied to the conductive field plate 200, such as a reference supply voltage, Vss. The reference supply voltage may be a ground reference voltage. In some embodiments, the conductive field plate 200 is not connected to a voltage source, but rather is left to float. In some embodiments, the contact opening 180 extends into the STI structure 105 to a depth of between about 50% to about 90% of the vertical thickness of the STI structure 105. The depth of the extension of the conductive field plate 200 into the STI structure 105 impacts the degree to which the surface electric field is affected by the conductive field plate 200. The depth is also selected to ensure that a sufficient thickness of dielectric material in the STI structure 105 remains to avoid forming a short between the conductive field plate 200 and the drift region 110D.

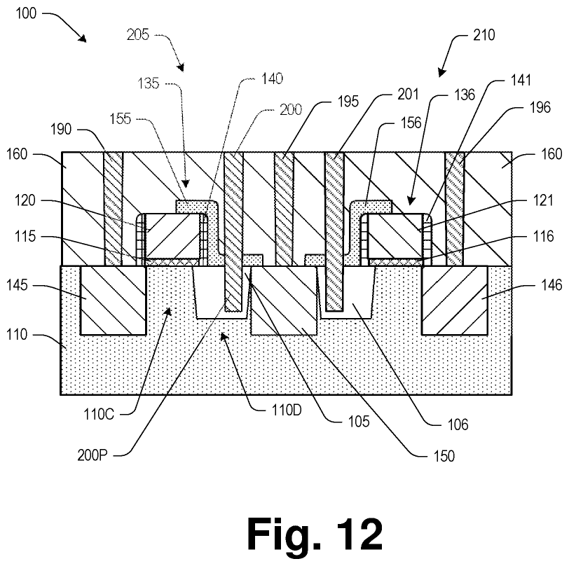

Referring to FIG. 12, the semiconductor structure 100 comprises a second DMOS device 210 adjacent the DMOS device 205, in accordance with some embodiments. In some embodiments, the second DMOS device 210 comprises an isolation structure 106 in the semiconductor layer 110 and a gate structure 136 having a gate dielectric layer 116 and a gate electrode layer 121. A sidewall spacer 141 is adjacent the gate dielectric layer 116 and the gate electrode layer 121. A source/drain region 146 is adjacent the gate structure 136. A dielectric layer 156 is over a portion of the gate structure 136, the isolation structure 106, and the source/drain region 150. A contact 196 extends through the dielectric layer 160 to contact the source/drain region 146. A conductive field plate 201 extends through the dielectric layer 160, the dielectric layer 156, and a portion of the isolation structure 106. The conductive field plate 201 reduces the surface electric field of the second DMOS device 210 to reduce the breakdown voltage.

The second DMOS device 210 may be formed as a mirror image of the DMOS device 205, and the second DMOS device 210 may share the source/drain region 150 with the DMOS device 205. In some embodiments, the DMOS device 205 and the second DMOS device 210 are formed using an integrated process flow with similar materials and processes. In some embodiments, the materials are adapted for the particular conductivity type of the DMOS device 205, 210. For example, the gate dielectric layer 116 of the second DMOS device 210 may be the same material as the gate dielectric layer 115 of the DMOS device 205. The material of the gate electrode layer 121 of the second DMOS device 210 may be different than the material of the gate electrode layer 120 of the DMOS device 205. The materials of the gate electrode layer 120 of the DMOS device 205 and the gate electrode layer 121 of the second DMOS device 210 may have one or more work function material (WFM) layers adapted for the conductivity type. Example p-type work function metals include Mo, Ru, Jr, Pt, PtSi, MoN, TiN, Al, W, HfN, WN, NiSiₓ, ZrSi₂, MoSi₂, and/or TaSi₂. At least some p-type work function materials have work functions greater than about 4.5. Example n-type work function metals include Ti, Al, Ta, ZrSi₂, Ag, TaN, TaAl, TaAlC, TiAlN, TaC, TaCN, TaSiN, TaSiₓ, Mn, and/or Zr. At least some n-type work function materials have work functions less than about 4.5. The WFM layer may comprise a plurality of layers. In some embodiments, a barrier layer is formed prior to the formation of WFM layer. The WFM layer is formed by at least one of CVD, PVD, electroplating, or other suitable techniques.

In some embodiments, materials of the source/drain regions 145, 150, 146 are adapted based on the conductivity type of the DMOS device 205, 210. One or more of the source/drain regions 145, 150, 146 may comprise a silicon alloy having an alloy species that affects a lattice constant of the source/drain region 145, 150, 146 relative to a lattice constant of the material forming the semiconductor layer 110. In some embodiments, the alloy species comprises germanium, tin, or other suitable material that causes the semiconductor material to have a larger lattice constant than the material forming the semiconductor layer 110 and generating a compressive stress. In some embodiments, the alloy species comprises carbon or other suitable material that causes the semiconductor material to have a smaller lattice constant than the material forming the semiconductor layer 110 and generating a tensile stress.

The DMOS device 205 may be an N-type device and the second DMOS device 210 may be a P-type device such that the DMOS device 205 and the DMOS device 205 form a complementary pair. DMOS devices 205, 210 forming a complementary pair may be used in various devices, such as logic devices, such as inverters, logic gates, latches, memory devices, such as static random access memory (SRAM) devices, and/or other suitable devices.

In some embodiments, a method of forming a semiconductor structure includes forming a first isolation structure in a semiconductor layer, forming a first gate structure adjacent a first side of the first isolation structure, forming a first source/drain region adjacent a second side of the first isolation structure, forming a second source/drain region adjacent the first gate structure, and forming a first dielectric layer having a porosity greater than a material of the first isolation structure over the first isolation structure. A first recess is formed in the first dielectric layer and the first isolation structure and a first conductive field plate is formed in the first recess.

In some embodiments, a semiconductor structure includes a semiconductor layer, a first isolation structure in the semiconductor layer, a first gate structure adjacent a first side of the first isolation structure, a first source/drain region adjacent a second side of the first isolation structure, a second source/drain region adjacent the first gate structure, and a first conductive field plate at least partially embedded in the first isolation structure.

In some embodiments, a semiconductor structure includes a semiconductor layer, a first isolation structure in the semiconductor layer over a first drift region, a first gate structure adjacent a first side of the first isolation structure and over a first channel region, and a first conductive field plate in the first isolation structure over the first drift region and having a lowermost surface below an uppermost surface of the first isolation structure and above a lowermost surface of the first isolation structure.

The foregoing outlines features of several embodiments so that those of ordinary skill in the art may better understand various aspects of the present disclosure. Those of ordinary skill in the art should appreciate that they may readily use the present disclosure as a basis for designing or modifying other processes and structures for carrying out the same purposes and/or achieving the same advantages of various embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is not limited thereto. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one or more of several implementations, such feature may be combined with one or more other features of the other implementations as may be desired and advantageous for any given or particular application.

What is claimed is:

1. A method of forming a semiconductor structure, comprising:
forming a first isolation structure in a semiconductor layer;
forming a first gate structure adjacent a first side of the first isolation structure;
forming a first source/drain region adjacent a second side of the first isolation structure;
forming a second source/drain region adjacent the first gate structure;
forming a first dielectric layer having a porosity greater than a material of the first isolation structure over the first isolation structure;
forming a first recess in the first dielectric layer and the first isolation structure; and
forming a first conductive field plate in the first recess.

2. The method of claim 1, comprising:
patterning the first dielectric layer to remove a first portion of the first dielectric layer over the semiconductor layer, a second portion of the first dielectric layer over a portion of the first gate structure, and a third portion of the first dielectric layer over the first source/drain region.

3. The method of claim 1, comprising:
forming a second dielectric layer over the first gate structure, the first source/drain region, and the first isolation structure;
forming a first opening in the second dielectric layer exposing the first source/drain region;
forming a second opening in the second dielectric layer, the first dielectric layer, and the first isolation structure to form the first recess;
forming a contact in the first opening contacting the first source/drain region; and
forming the first conductive field plate in the second opening and in the first recess.

4. The method of claim 3, wherein forming the first conductive field plate comprises:
forming a line portion of the first conductive field plate in the second opening; and
forming a plug portion of the first conductive field plate in the first recess.

5. The method of claim 1, comprising:
forming a second isolation structure in the semiconductor layer adjacent the first gate structure;
forming a second recess in the second isolation structure; and
forming a second conductive field plate in the second recess.

6. The method of claim 1, comprising:
forming a second isolation structure in the semiconductor layer adjacent the first source/drain region;
forming a second gate structure adjacent the second isolation structure;
forming a third source/drain region adjacent the second gate structure;
forming a second recess in the second isolation structure; and
forming a second conductive field plate in the second recess.

7. A semiconductor structure, comprising:
a semiconductor layer;
a first isolation structure in the semiconductor layer;
a first gate structure adjacent a first side of the first isolation structure;
a first source/drain region adjacent a second side of the first isolation structure;
a second source/drain region adjacent the first gate structure; and
a first conductive field plate at least partially embedded in the first isolation structure.

8. The semiconductor structure of claim 7, comprising:
a dielectric layer over the semiconductor layer, over the first gate structure, and over the first isolation structure, wherein:
the first conductive field plate is at least partially embedded in the dielectric layer.

9. The semiconductor structure of claim 8, wherein the dielectric layer comprises:
a first portion over a portion of the first gate structure;
a second portion over a portion of the first source/drain region; and
a third portion over a portion of the first isolation structure.

10. The semiconductor structure of claim 7, comprising:
a dielectric layer over the first gate structure, the first source/drain region, and the first isolation structure; and
a contact in the dielectric layer contacting the first source/drain region, wherein:
the first conductive field plate is at least partially embedded in the dielectric layer.

11. The semiconductor structure of claim 10, wherein the first conductive field plate comprises:
a line portion embedded in the dielectric layer; and
a plug portion embedded in the first isolation structure.

12. The semiconductor structure of claim 7, comprising:
a second isolation structure in the semiconductor layer adjacent the first gate structure; and
a second conductive field plate at least partially embedded in the second isolation structure.

13. The semiconductor structure of claim 7, comprising:
a second isolation structure in the semiconductor layer adjacent the first source/drain region;
a second gate structure adjacent the second isolation structure;
a third source/drain region adjacent the second gate structure; and
a second conductive field plate at least partially embedded in the second isolation structure.

14. A semiconductor structure, comprising:
a semiconductor layer;
a first isolation structure in the semiconductor layer over a first drift region;
a first gate structure adjacent a first side of the first isolation structure and over a first channel region; and
a first conductive field plate in the first isolation structure over the first drift region and having a lowermost surface below an uppermost surface of the first isolation structure and above a lowermost surface of the first isolation structure.

15. The semiconductor structure of claim 14, comprising:
a first source/drain region adjacent a second side of the first isolation structure; and
a second source/drain region adjacent the first gate structure.

16. The semiconductor structure of claim 15, comprising:
a dielectric layer over the first gate structure, the first source/drain region, and the first isolation structure; and
a contact in the dielectric layer contacting the first source/drain region, wherein:
the first conductive field plate is at least partially embedded in the dielectric layer.

17. The semiconductor structure of claim 14, comprising:
a dielectric layer over the semiconductor layer, over the first gate structure, and over the first isolation structure, wherein:
the first conductive field plate is at least partially embedded in the dielectric layer.

18. The semiconductor structure of claim 17, wherein the first conductive field plate comprises:
a line portion embedded in the dielectric layer; and
a plug portion embedded in the first isolation structure.

19. The semiconductor structure of claim 14, comprising:
a first source/drain region adjacent a second side of the first isolation structure;
a second source/drain region adjacent the first gate structure;
a second isolation structure in the semiconductor layer over a second drift region;
a second gate structure adjacent the second isolation structure over a second channel region;
a third source/drain region adjacent the second gate structure; and
a second conductive field plate in the second isolation structure over the second drift region and having a lowermost surface at depth of at least 50% of a thickness of the second isolation structure.

20. The semiconductor structure of claim 14, wherein:
the lowermost surface below an uppermost surface of the first isolation structure and above a lowermost surface is at a depth of at least 50% of a thickness of the first isolation structure.
